(19) United States
(12) Patent Application Publication
(10) Pub. No.: US 2009/0160515 A1
(43) Pub. Date: Jun. 25, 2009

(54) Auto-tracking clock circuitry

(76) Inventor: James Douglas Warnock, Somers, NY (US)

Correspondence Address: HAMILTON & TERRILE, LLP;IBM Austin, P.O. BOX 203518, AUSTIN, TX, 78720, US

(21) Appl. No.: 11/959,907

(22) Filed: Dec. 19, 2007

(51) Int. Cl. H03K 5/04

(52) U.S. Cl. 327/175

(57) ABSTRACT

A system and method for generating a clock signal is disclosed. In various embodiments of the invention disclosed herein, a global clock signal is generated and provided as an input to local clock circuitry operable to generate a local clock signal therefrom. The local clock circuitry comprises logic components that are susceptible to negative bias thermal instability (NBTI) effects resulting in degradation of the local clock signal. Clock propagation adjustment circuitry is used to modify the duty cycle of the global clock signal to compensate for the degradation resulting from NBTI effects thereby providing an optimized local clock signal.

### BACKGROUND OF THE INVENTION

1. Field of the Invention

The present invention relates in general to the field of integrated circuits. More specifically, the present invention relates to improvements in the mitigation of the effects of negative bias thermal instability in integrated circuits.

2. Description of the Related Art

In modern microprocessors, there are many situations where critical timing paths are launched from the falling edge of a globally distributed clock signal, and then terminated by a timing constraint derived from the rising edge of the clock signal (or vice versa, launched on rising, captured from falling). These types of timing paths are generally referred to as “half-cycle paths,” and arise very commonly in dynamic logic, where the time allowed for evaluation is set by the width of one clock phase, and the time for pre-charging is set by the other.

These types of timing paths are likely to cause serious timing problems for a high-speed chip for several reasons. With a 50-50 duty cycle clock (i.e., clock signal is high for half of a cycle, and low for the other half), each half-cycle path has only 50% of the total cycle time available. If the total cycle time is T, then the time available for such a timing path is T/2. If the path is mistimed by an amount “t,” the overall cycle time of the processor has to increase by an amount of 2t, since only half of the increased cycle time is available for the half cycle path. By comparison, for full cycle paths, which are launched from one clock edge, then captured from a similar edge one cycle later, a timing miss of “t” results in an increase of “t” to the overall processor cycle time. Thus timing misses for ½ cycle paths can have a large impact on the overall microprocessor cycle time.

Successive same-direction clock edges will in general be very repeatable, because each edge is simply a repeat of the previous cycle edge, with uncertainty only introduced by clock jitter. However, opposite-direction edges may have significantly different slews, due to process variations. This difference can translate into additional uncertainty for half-cycle paths. The clock waveform may be distorted due to local or global process variations, so that some chips may have a perfect 50-50 duty cycle, but others may have either larger or smaller duty cycles depending on the details of the process.

For all the above reasons, half-cycle paths will often limit the operating frequency of a microprocessor or other integrated circuit. State of the art processors may have active duty cycle correction circuitry to try to help mitigate this problem. However, modern complementary metal oxide semiconductor (CMOS) technology is subject to Negative Bias Thermal Instability (NBTI) effects whereby, over time, the threshold voltage for P-type field effect transistors (pFETs) may increase, thereby slowing down the speed at which they can switch.

The effects of NBTI stress reduce the performance of CMOS circuitry in two ways. NBTI stress simultaneously decreases the amount of time available for precharge by distorting the local clock waveform, while also increasing the amount of time needed for precharge, by weakening the precharge pFET. As a result the NBTI stress will cause the circuit to fail over time, if there is no compensation for this effect.

There are several conventional approaches to compensating for the effects of NBTI. In one approach, extra margin is added to the test results obtained when testing hardware at the start. As the circuits degrade as a result of the effects of NBTI, there will still be adequate timing margin. This solution is undesirable, however, since the performance of the design has to be downgraded to accommodate the predicted stress. Also, since the amount of stress is not totally predictable, extra margin has to be added for variability.

In another approach, the starting clock waveform is skewed in some manner to give more time to the precharge, and less time to the evaluate. Unfortunately, this just leaves less time for the critical evaluate phase. In practical terms this means that the margin needed is spread over the evaluate and precharge cycle halves, but additional margin is still needed. Also, the optimal amount of skewing may be process dependent, making it hard to obtain the best compromise between evaluate time and precharge time on every chip. The uncertainty in the eventual NBTI shift also means that margins need to be increased as well.

Another approach involves adjustments to the active global clock duty cycle. These adjustments tend to be complicated, may increase clock jitter, and do not necessarily track well with the underlying problem (pFET degradation). Ideally, as local clock components and precharge devices wear out, the duty cycle should shift in such a way as to give more time for these circuits to perform precharge and evaluation.

In view of the foregoing, there is a need for a system and method for reducing the effects of NBTI on the clock circuits and precharge circuits implemented in integrated circuits. The various embodiments of the present invention, described in greater detail hereinbelow, provide a solution for reducing the effects of NBTI, as discussed hereinabove.

### SUMMARY OF THE INVENTION

Embodiments of the invention provide clock generation and/or clock distribution circuitry comprising additional transistors to cause the clock duty cycle to shift over time as pFETs slow down as a result of NBTI effects. The additional transistors are pFETs that shift over time at the same rate as the pFETs currently used in the clock generation and/or clock distribution circuitry. Since the clock shift will be caused by the pFET NBTI shift, it will track and compensate for the shift of the local clock and the precharge device, since the same mechanism is responsible for the shift. In addition, embodiments of the invention provide a means of adjusting both the direction and amount of clock shift, to compensate for specific half-cycle critical paths that are limiting the integrated circuit's performance as the circuit ages.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 depicts an example of a dynamic gate, with local clock circuitry;

FIG. 2a depicts the time shift of a clock signal as a result of NBTI stress on pFET devices used in the local clock circuitry shown in FIG. 1;

FIG. 2b depicts the impact on the output waveform resulting from NBTI stress on pFET precharge devices;

FIG. 3 depicts a global clock propagation circuit;

FIG. 4a depicts a modified global clock propagation circuit;

FIG. 4b depicts an alternate modified global clock distribution circuit; and

FIG. 5 depicts a configurable and/or adaptive global clock distribution circuit.

### DETAILED DESCRIPTION

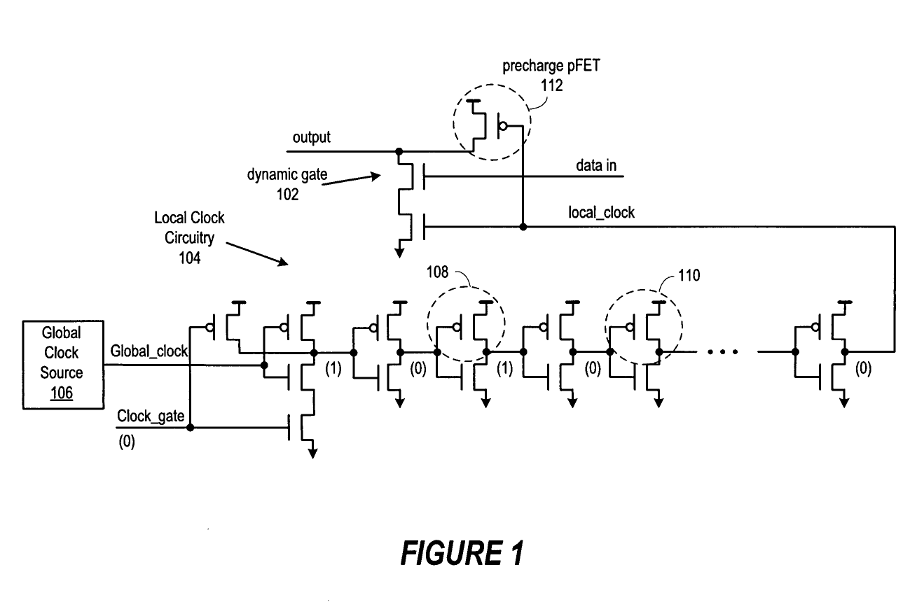

FIG. 1 shows an example of a dynamic gate 102 along with a symbolic representation of the local clock circuitry 104 used to generate and propagate a global clock signal generated by global clock source 106. The circuitry shown in FIG. 1 will be used to illustrate the impact of NBTI shift on the propagation of a global clock signal in a typical half-cycle path. Those of skill in the art will recognize that there are numerous other dynamic gates that might be much more complicated than the example shown, and the clock circuitry may also be considerably more complicated, with various logic gates for qualifying the clock signal, and more stages of gain for distribution/propagation of the local clocks.

In the circuitry shown in FIG. 1, when dynamic gate 102 is inactive, “clock_gate” is generally held low to save power, and downstream nodes are held at the fixed values as indicated. The circuit may spend a large fraction of time with clock_gate at “0,” especially if it is part of a large array or register file, when only one out of “n” circuits (where “n” can be large) is ever accessed, even when the processor is highly active. Those pFETs, e.g., pFETs 108 and 110, having their gate tied to “0” for significant periods of time will experience an excessive NBTI stress, whereas the pFETs having their gates gate generally at “1” will experience very little NBTI stress. As a result, the pFETs 108 and 110 will become weaker over time, thereby affecting the clock waveform. Since only alternate pFETs are affected, only one edge of the clock waveform is strongly affected; therefore, the clock waveform becomes asymmetric. Also, since the precharge pFET 112 has its gate held at “0” for a significant period of time, it is held in a NBTI high-stress state and, therefore, it will be weakened, resulting in a longer time requirement for precharging.

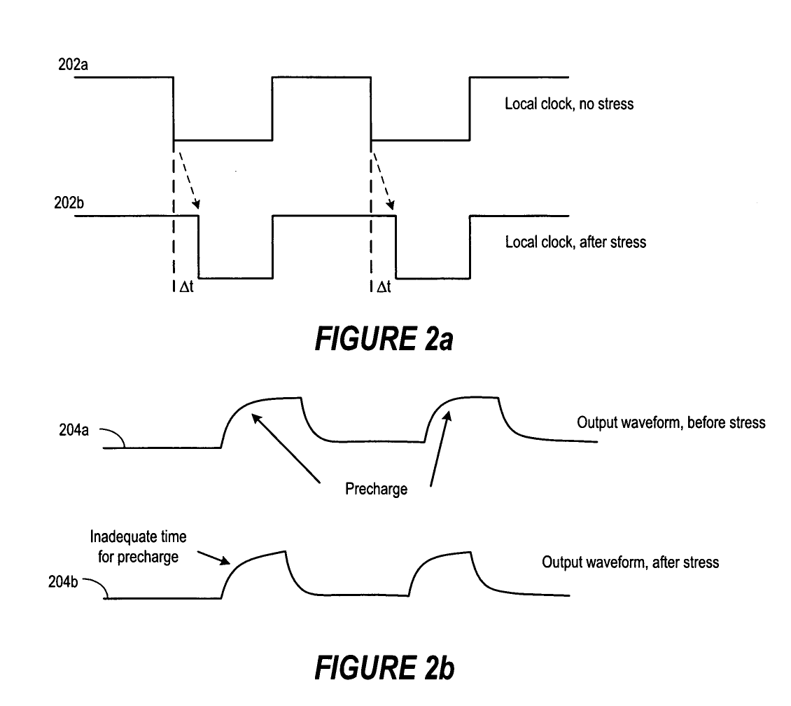

The net effect of the NBTI stress discussed above is illustrated in FIGS. 2a and 2b. The waveforms 202a and 202b shown in FIG. 2a illustrate a decrease in time, Δt, available for precharge as a result of the clock waveform distortion caused by weakening of alternate pFETs such as 108 and 110 because of NBTI effects. The waveforms 204a and 204b shown FIG. 2b illustrate that the effects of NBTI stress also increase the amount of time required for precharge, by weakening the precharge pFET 112. As can be seen from the aforementioned waveforms, the NBTI stress will cause the circuit to fail over time, if there is no compensation for the NBTI stress.

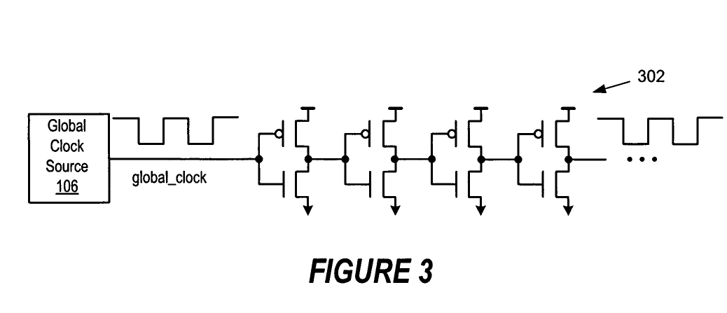

FIG. 3 shows a circuit plurality of CMOS logic gates 302 comprising pFETs and nFETs for propagating a global clock signal. For simplicity, the gates are all shown as inverters, although, in practice, they could be implemented using any CMOS gate. For discussion purposes, a circuit comprising a plurality of logic gates for propagating a clock signal will sometimes hereinafter be referred to as a “chain” of gates. With a reasonably symmetric input global clock waveform, all pFETs will see identical NBTI shifts over time (except for random statistical variations, which will tend to average out in a given chain of gates). This is because each pFET spends about half of the time with gate at “0,” source and drain at “1” (high stress state), and half the time with gate at “1,” source and drain “0” (low stress for NBTI). Therefore, the clock waveform will not be appreciably changed or distorted as the pFETs experience NBTI shift, since all pFETs will shift by about the same amount.

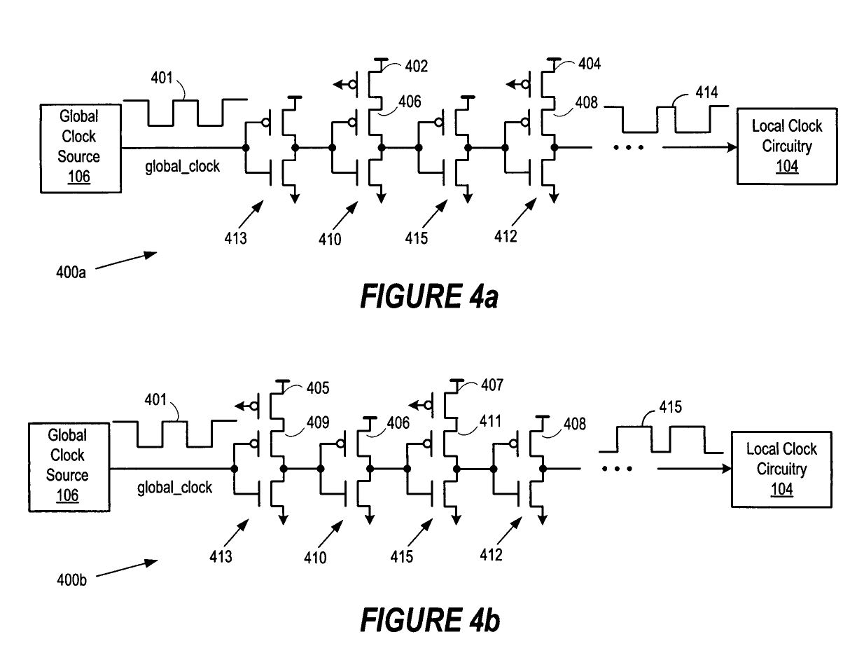

FIGS. 4a and 4b illustrate embodiments of logic circuits comprising a plurality of logic gates that are configured to modify the duty cycle of a clock signal 401 as it propagates though the logic gates. In the embodiment of the clock propagation circuit 400a, shown in FIG. 4a, the pFETs 402 and 404 are coupled to pFETs 406 and 408, respectively, in the “even” gates 410 and 412. Since the gates of pFETs 402 and 404 are tied permanently to ground, these pFETs will experience much larger NBTI shifts over time than pFETs whose gates receive the alternating global clock signal. The large NBTI shift occurs because DC stress tends to enhance the NBTI shift, and also because the stress is applied to these devices 100% of the time, instead of only 50% of the time. At time, t=0, (before any NBTI shift has occurred) the output clock waveform will be essentially identical to the input wave form. As NBTI shift occurs, preferentially in the gate-tied pFETs 402 and 404, the duty cycle of the clock waveform will shift, and this shift in the duty cycle can be used to compensate for NBTI effects in a local clock circuit to ensure that an optimal duty cycle is maintained even after NBTI shifts occur. For example, in the circuit 400a shown in FIG. 4a, the pull-up speed of the gates 410 and 412 will increase disproportionately over time, so that the global clock waveform will be skewed towards having a longer “down” (i.e., logic “0”) time vs “up” (i.e., logic “1”) time, as illustrated by clock waveform 414. The clock propagation logic circuit 400a can, therefore, be used to effectively compensate for the local clock duty cycle shift described earlier in connection with FIG. 1, giving more time to the precharge operation as NBTI shift increases.

In another embodiment, the clock propagation circuit 400b, shown in FIG. 4b, comprises pFETs 405 and 407 that are coupled to pFETs 409 and 411, respectively, in the “odd” gates 413 and 415. As discussed above, since the gates of pFETs 405 and 407 are tied permanently to ground, these pFETs will experience much larger NBTI shifts over time than pFETs whose gates receive the alternating global clock signal. Again, as NBTI shift occurs, the duty cycle of the clock waveform will shift, and this shift in the duty cycle can be used to compensate for NBTI effects in a local clock circuit to ensure that an optimal duty cycle is maintained even after NBTI shifts occur. In the circuit shown in FIG. 4b, the pull-up speed of the gates 413 and 415 will increase disproportionately over time, so that the global clock waveform will be skewed towards having a longer “up” (i.e., logic “1”) time vs “down” (i.e., logic “0”) time. The clock propagation logic circuit 400a can, therefore, be used to effectively offset a duty cycle shift in the opposite direction due to NBTI effects on logic components in the local clock propagation logic circuit. Those of skill in the art of VLSI design will recognize that it is possible to design several chains of different lengths (inducing different amounts of NBTI stress-induced duty cycle shift over time), designed to shift the duty cycle in different directions over time.

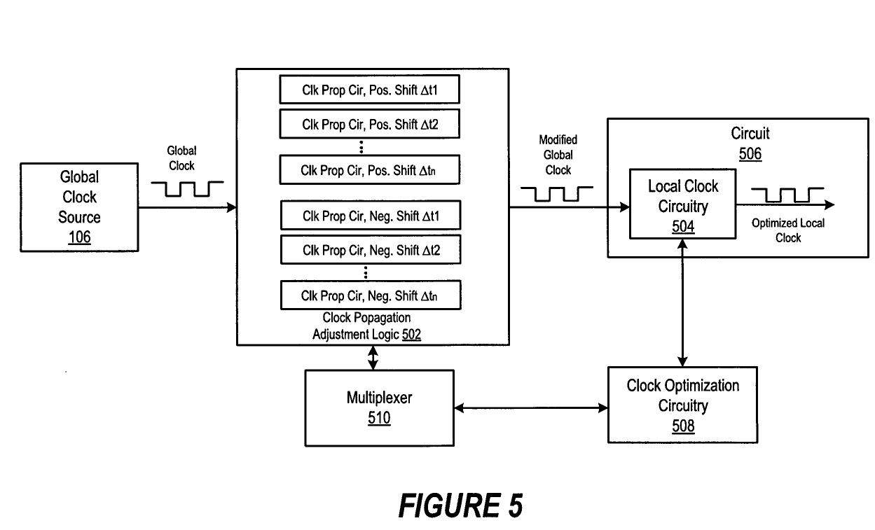

FIG. 5 shows a system for using a plurality of propagation logic circuits, having pFETs with performance characteristics modified by the effects of NBTI, such as the circuits discussed above in connection with FIGS. 4a and 4b, to modify the duty cycle of a first clock, such as a global clock, to compensate for duty cycle characteristics of a second clock, such as a local clock. A plurality of clock propagation adjustment logic circuits 502 are provided, with individual clock propagation circuits having predetermined magnitudes of positive or negative duty cycle shifts. A clock optimization circuit 508 is operable to monitor the clock propagation characteristics of local clock propagation circuitry 504 in a circuit 506, and generates a local clock quality output signal corresponding to degradation, for example, shifts in the duty cycle of the local clock signal resulting from NBTI effects. Depending on the desired clock duty cycle and the current duty cycle characteristics of the local clock propagation circuitry 504, the clock optimization circuit 508 generates a control signal that causes a multiplexer 510 to generate a control signal to couple an appropriate clock adjustment clock propagation circuit 502 to modify the global clock duty cycle. The modified global clock signal is then provided to the local clock circuit 504 to generate an optimized local clock signal.

The global and local clock circuitry described herein is embedded in a plurality of data processing circuits in integrated circuits that are used in information handling systems and in a wide range of other applications. Those of skill in the art will understand that the embodiments described herein will result in improved performance and an increased effective lifetime for such products. Although the present invention has been described in detail, it should be understood that various changes, substitutions and alterations can be made hereto without departing from the spirit and scope of the invention as defined by the appended claims.

What is claimed is:

1. A system for generating a clock signal, comprising:
a source for generating a global clock signal;
local clock circuitry operable to receive the global clock signal and to generate a local clock signal therefrom, the local clock circuitry comprising logic components susceptible to negative bias thermal instability (NBTI) effects resulting in degradation of the local clock signal; and
clock propagation adjustment circuitry operable to modify the duty cycle of the global clock signal whereby the local clock signal generated by the local clock circuitry is optimized to compensate for the degradation resulting from NBTI effects.

2. The system of claim 1, wherein the logic components susceptible to NBTI effects comprise p-type metal oxide semiconductor field-effect semiconductors (pFETs).

3. The system of claim 1, wherein the clock propagation adjustment circuitry is operable to generate a negative shift in the duty cycle of the global clock signal.

4. The system of claim 1, wherein the clock propagation adjustment circuitry is operable to generate a positive shift in the duty cycle of the global clock signal.

5. The system of claim 1, further comprising clock optimization circuitry operable to monitor the local clock signal generated by the local clock circuitry and to provide a local clock quality output signal corresponding to shifts in the duty cycle of the local clock signal resulting from NBTI effects.

6. The system of claim 5, wherein a multiplexer is operable to receive the local clock quality output signal and, in response thereto, to generate a control signal to couple a predetermined clock propagation adjustment circuit to the local clock circuitry to optimize the local clock generated therefrom.

7. The system of claim 6, wherein the predetermined clock propagation adjustment circuit is selected from a plurality of clock propagation adjustment circuits operable to provide a predetermined magnitude of positive shift or negative shift in the duty cycle of the global clock signal.

8. A method for generating a clock signal, comprising:
generating a global clock signal;
providing said global clock signal to local clock circuitry operable to generate a local clock signal therefrom, the local clock circuitry comprising logic components susceptible to negative bias thermal instability (NBTI) effects resulting in degradation of the local clock signal; and
clock propagation adjustment circuitry operable to modify the duty cycle of the global clock signal whereby the local clock signal generated by the local clock circuitry is optimized to compensate for the degradation resulting from NBTI effects.

9. The method of claim 8, wherein the logic components susceptible to NBTI effects comprise p-type metal oxide semiconductor field-effect semiconductors (pFETs).

10. The method of claim 8, wherein the clock propagation adjustment circuitry is operable to generate a negative shift in the duty cycle of the global clock signal.

11. The method of claim 8, wherein the clock propagation adjustment circuitry is operable to generate a positive shift in the duty cycle of the global clock signal.

12. The method of claim 8, further comprising clock optimization circuitry operable to monitor the local clock signal generated by the local clock circuitry and to provide a local clock quality output signal corresponding to shifts in the duty cycle of the local clock signal resulting from NBTI effects.

13. The method of claim 12, wherein a multiplexer is operable to receive the local clock quality output signal and, in response thereto, to generate a control signal to couple a predetermined clock propagation adjustment circuit to the local clock circuitry to optimize the local clock generated therefrom.

14. The method of claim 13, wherein the predetermined clock propagation adjustment circuit is selected from a plurality of clock propagation adjustment circuits operable to provide a predetermined magnitude of positive shift or negative shift in the duty cycle of the global clock signal.

15. An information handling system, comprising:
a plurality of integrated circuits operably coupled to process data, wherein at least one integrated circuit comprises:
a source for generating a global clock signal;
local clock circuitry operable to receive the global clock signal and to generate a local clock signal therefrom, the local clock circuitry comprising logic components susceptible to negative bias thermal instability (NBTI) effects resulting in degradation of the local clock signal; and
clock propagation adjustment circuitry operable to modify the duty cycle of the global clock signal whereby the local clock signal generated by the local clock circuitry is optimized to compensate for the degradation resulting from NBTI effects.

16. The information handling system of claim 15, wherein the logic components susceptible to NBTI effects comprise p-type metal oxide semiconductor field-effect semiconductors (pFETs).

17. The information handling system of claim 15, wherein the clock propagation adjustment circuitry is operable to generate a negative shift in the duty cycle of the global clock signal.

18. The information handling system of claim 15, wherein the clock propagation adjustment circuitry is operable to generate a positive shift in the duty cycle of the global clock signal.

19. The information handling system of claim 18, further comprising clock optimization circuitry operable to monitor the local clock signal generated by the local clock circuitry and to provide a local clock quality output signal corresponding to shifts in the duty cycle of the local clock signal resulting from NBTI effects.

20. The information handling system of claim 19, wherein a multiplexer is operable to receive the local clock quality output signal and, in response thereto, to generate a control signal to couple a predetermined clock propagation adjustment circuit to the local clock circuitry to optimize the local clock generated therefrom.
